(19) United States
(12) Patent Application Publication
(10) Pub. No.: US 2024/0372317 A1
(43) Pub. Date: Nov. 7, 2024

(54) OPTICAL MODULATOR INTEGRATED SEMICONDUCTOR LASER AND SEMICONDUCTOR LIGHT-EMITTING DEVICE

(71) Applicant: SUMITOMO ELECTRIC DEVICE INNOVATIONS, INC., Yokohama-shi (JP)

(72) Inventor: Hiromitsu KAWAMURA, Yokohama-shi (JP)

(73) Assignee: SUMITOMO ELECTRIC DEVICE INNOVATIONS, INC., Yokohama-shi (JP)

(21) Appl. No.: 18/649,078

(22) Filed: Apr. 29, 2024

(30) Foreign Application Priority Data
May 1, 2023 (JP) 2023-075845

(51) Int. Cl. H01S 5/02345; H01S 5/026

(52) U.S. Cl. CPC H01S 5/02345; H01S 5/026

(57) ABSTRACT

An optical modulator integrated semiconductor laser includes a laser unit outputting a laser beam, an optical modulation unit modulating the laser beam, a signal pad for connection to a first wire for inputting a modulation signal to the optical modulation unit, and a first pad for connection to a second wire holding a ground potential.

### CROSS-REFERENCE TO RELATED APPLICATION

This application claims the benefit of priority from Japanese Patent Application No. 2023-075845, filed on May 1, 2023, the entire contents of which are incorporated herein by reference.

### TECHNICAL FIELD

The present disclosure relates to an optical modulator integrated semiconductor laser and a semiconductor light-emitting device.

### BACKGROUND

Patent Document 1 (Japanese Unexamined Patent Publication No. 2001-308130) discloses a technique of a high-frequency circuit, a module in which the high-frequency circuit is mounted, and a communicator. The high-frequency circuit has a configuration in which a signal line for transmitting a high-frequency signal is connected with a capacitive element by a first bonding wire and the capacitive element is connected with a termination resistor for matching impedance by a second bonding wire. In such a high-frequency circuit, a magnitude of a characteristic impedance of a transmission line formed by the first bonding wire, the second bonding wire, and the capacitive element is larger than a magnitude of a characteristic impedance on an input side of a high-frequency signal. In the high-frequency circuit, a magnitude of an inductance of the first bonding wire is smaller than a magnitude of an inductance of the second bonding wire.

### SUMMARY

The present disclosure provides an optical modulator integrated semiconductor laser. The optical modulator integrated semiconductor laser includes: a laser unit including an active region and outputting a laser beam; an optical modulation unit including a modulation region and modulating the laser beam; and a first pad for connection to a wire holding a ground potential. The optical modulation unit includes a modulation electrode for transmitting or cutting off the laser beam based on an input modulation signal and a signal pad connected to the modulation electrode and configured for connection to another wire for inputting the modulation signal in the modulation region.

### BRIEF DESCRIPTION OF THE DRAWINGS

FIG. 1 is a plan view illustrating a transmitting small-sized optical device according to a first embodiment of the present disclosure.

FIG. 2 is a circuit diagram illustrating a transmitting small-sized optical circuit according to the first embodiment of the present disclosure.

FIG. 3 is a perspective view illustrating a semiconductor light-emitting device according to the first embodiment of the present disclosure.

FIG. 4 is a plan view illustrating the semiconductor light-emitting device according to the first embodiment of the present disclosure.

FIG. 5 is a sectional view along line V-V in FIG. 4.

FIG. 6 is a perspective view illustrating a semiconductor light-emitting device according to a first modification.

FIG. 7 is a plan view illustrating the semiconductor light-emitting device according to the first modification.

FIG. 8 is a perspective view illustrating a semiconductor light-emitting device according to a second modification.

FIG. 9 is a plan view illustrating the semiconductor light-emitting device according to the second modification.

FIG. 10 is a perspective view illustrating a semiconductor light-emitting device according to a third modification.

FIG. 11 is a plan view illustrating the semiconductor light-emitting device according to the third modification.

FIG. 12 is a perspective view illustrating a semiconductor light-emitting device according to a fourth modification.

FIG. 13 is a plan view illustrating the semiconductor light-emitting device according to the fourth modification.

FIG. 14 is a perspective view illustrating a semiconductor light-emitting device according to a comparative example.

### DETAILED DESCRIPTION

### Problem to be Solved by Present Disclosure

With an increase in speed and capacity of optical communication, there is need for an increase in bandwidth of a semiconductor light-emitting element of a semiconductor light-emitting device. However, mismatch in input impedance is likely to occur due to the increase in bandwidth of an element. A loss of an input modulation signal increases, for example, in a junction of a transmission line in the semiconductor light-emitting device due to the mismatch in input impedance. Accordingly, for example, a modulation signal may not be satisfactorily transmitted to an optical modulation element.

### Effects of Present Disclosure

According to the present disclosure, it is possible to provide an optical modulator integrated semiconductor laser and a semiconductor light-emitting device that can reduce a loss of a modulation signal due to mismatch in impedance.

### DESCRIPTION OF EMBODIMENTS OF PRESENT DISCLOSURE

Details of embodiments of the present disclosure will be first described in a list.

[1] An optical modulator integrated semiconductor laser according to an embodiment of the present disclosure includes: a laser unit outputting a laser beam; an optical modulation unit modulating the laser beam; a signal pad for connection to a first wire for inputting a modulation signal to the optical modulation unit; and a first pad for connection to a second wire holding a ground potential.

The optical modulator integrated semiconductor laser according to [1] includes the signal pad and the first pad. Accordingly, wires can be connected to the signal pad and the first pad. The second wire connected to the first pad holds the ground potential. Accordingly, a modulation signal passing through the first wire connected to the signal pad advances along with the ground potential. Accordingly, it is possible to decrease mismatch in input impedance. As a result, it is possible to reduce a loss of a modulation signal due to mismatch in impedance.

[2] The optical modulator integrated semiconductor laser according to [1] may further include a second pad for connection to a third wire holding the ground potential. The third wire connected to the second pad holds the ground potential. Accordingly, a modulation signal passing through the first wire connected to the signal pad disposed between the first pad and the second pad is sandwiched in the ground potential. As a result, it is possible to further decrease mismatch in input impedance. Accordingly, it is possible to further reduce a loss of the modulation signal due to the mismatch in impedance.

[3] In the optical modulator integrated semiconductor laser according to [1], the first pad and the signal pad may be provided in the optical modulation unit. Accordingly, the first pad is disposed at a position close to the signal pad. As a result, a distance between the first wire through which the modulation signal passes and the second wire holding the ground potential becomes smaller, and it is possible to more easily achieve match in input impedance.

[4] A semiconductor light-emitting device according to another embodiment of the present disclosure includes: the optical modulator integrated semiconductor laser according to any one of [1] to [3]; and a transmission line connected to the optical modulation unit to transmit a modulation signal. The transmission line includes a signal line for transmitting the modulation signal and a ground potential line holding the ground potential. The signal pad is connected with the signal line by the first wire, and the first pad provided on one side of the signal pad is connected with the ground potential line by the second wire.

In the semiconductor light-emitting device according to [4], the first pad is connected to the ground potential line by the second wire. Accordingly, the second wire holding the ground potential can be provided in the optical modulator integrated semiconductor laser. The signal line is connected to the first wire. The ground potential line is connected to the second wire. In general, since the signal line and the ground potential line of the transmission line are arranged side by side, the first wire and the second wire are arranged side by side with each other. Accordingly, the modulation signal progresses side by side with the ground potential even after the modulation signal has gotten away from the signal line. As a result, it is possible to decrease mismatch in impedance between the signal line and the first wire. Accordingly, it is possible to reduce a loss of the modulation signal due to the mismatch in impedance.

[5] In the semiconductor light-emitting device according to [4], a second pad may be provided on another side of the signal pad. For example, when the second pad is connected with the ground potential line by the third wire, the third wire holds the ground potential. Accordingly, the first wire disposed along with the second wire and the third wire is sandwiched in the ground potential. Therefore, the modulation signal passing through the first wire progresses side by side with the ground potential. As a result, it is possible to further decrease mismatch in impedance between the signal line and the first wire. Accordingly, it is possible to further reduce a loss of the modulation signal due to the mismatch in impedance.

[6] The semiconductor light-emitting device according to [4] may further include: a termination unit provided on the opposite side of the transmission line with respect to the optical modulation unit and configured to reduce reflection of the modulation signal; a fourth wire; and a fifth wire. The termination unit includes a first wiring pattern, a resistor of which one end is connected to the first wiring pattern, and a second wiring pattern to which another end of the resistor is connected. The first wiring pattern is connected with the signal pad by the fourth wire. The second wiring pattern is connected with the first pad by the fifth wire. In this case, the fifth wire holds the ground potential. The fourth wire and the fifth wire are arranged side by side with each other. Accordingly, the modulation signal propagating in the fourth wire progresses side by side with the ground potential. As a result, it is possible to further decrease mismatch in impedance between the first wire and the fourth wire. Accordingly, it is possible to further reduce a loss of the modulation signal due to the mismatch in impedance.

[7] The semiconductor light-emitting device according to [6] may further include: a sixth wire; and a second pad provided on another side of the signal pad. The second wiring pattern may be connected with the second pad by the sixth wire. In this case, the third wire and the sixth wire hold the ground potential. Accordingly, the first wire arranged along with the second wire and the third wire is sandwiched in the ground potential. Similarly, the third wire arranged along with the fifth wire and the sixth wire is sandwiched in the ground potential. Accordingly, the modulation signal passing through the first wire and the third wire progresses side by side with the ground potential. As a result, it is possible to further decrease mismatch in impedance between the signal line and the first wire or the third wire. Accordingly, it is possible to further reduce a loss of the modulation signal due to the mismatch in impedance.

[8] In the semiconductor light-emitting device according to [7], the second wiring pattern may be connected to only the resistor, the fifth wire, and the sixth wire. Accordingly, since a current returning to the ground passes through only the fifth wire and the sixth wire, an amount of current of an input modulation current is balanced with an amount of current flowing in the wire holding the ground potential. As a result, it is possible to improve accuracy of match in input impedance.

[9] In the semiconductor light-emitting device according to [6], the second wiring pattern may be connected to only the resistor and the fifth wire. Accordingly, since a current returning to the ground passes through only the fifth wire, an amount of current of an input modulation current is balanced with an amount of current flowing in the wire holding the ground potential. As a result, it is possible to improve accuracy of match in input impedance.

[10] In the semiconductor light-emitting device according to [4] or [6], the first wire and the second wire may be provided in parallel with each other. By providing the first wire and the second wire to be parallel with each other, it is possible to more easily decrease mismatch in impedance between the signal line and the first wire. Accordingly, it is possible to further reduce a loss of the modulation signal due to mismatch in impedance.

### Details of Embodiment of Present Disclosure

Specific examples of an optical modulator integrated semiconductor laser and a semiconductor light-emitting device according to the present disclosure will be described below with reference to the accompanying drawings. The present disclosure is not limited to these examples, is defined by the appended claims, and is intended to include all modifications within meanings and scopes equivalent to the claims. In the following description, the same elements in description with reference to the drawings will be referred to by the same reference signs, and repeated description thereof will be omitted. In the following description, connection means electrical connection and includes connection via an electronic component such as a resistor in addition to connection via conductive line of which an electrical resistance is substantially zero unless otherwise mentioned.

### First Embodiment

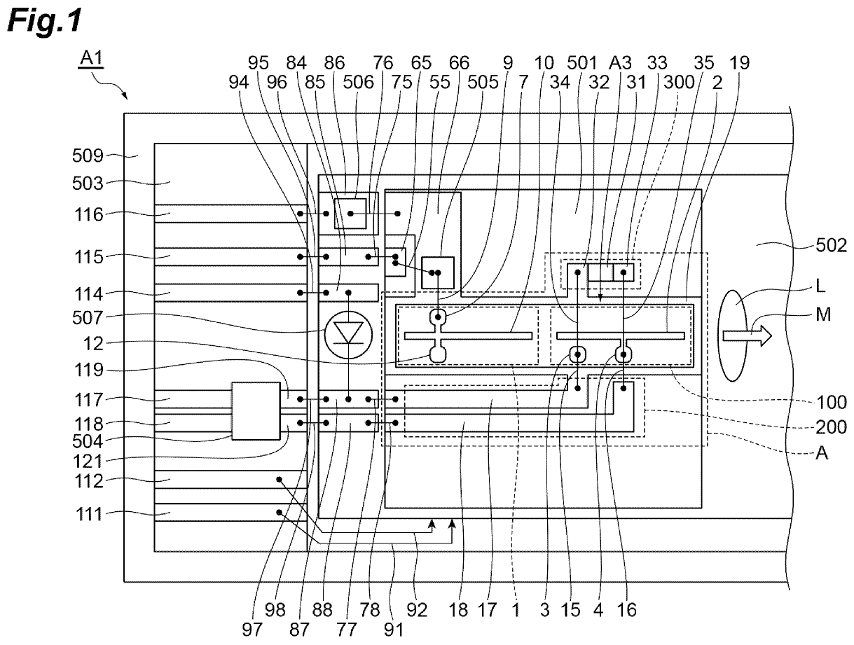

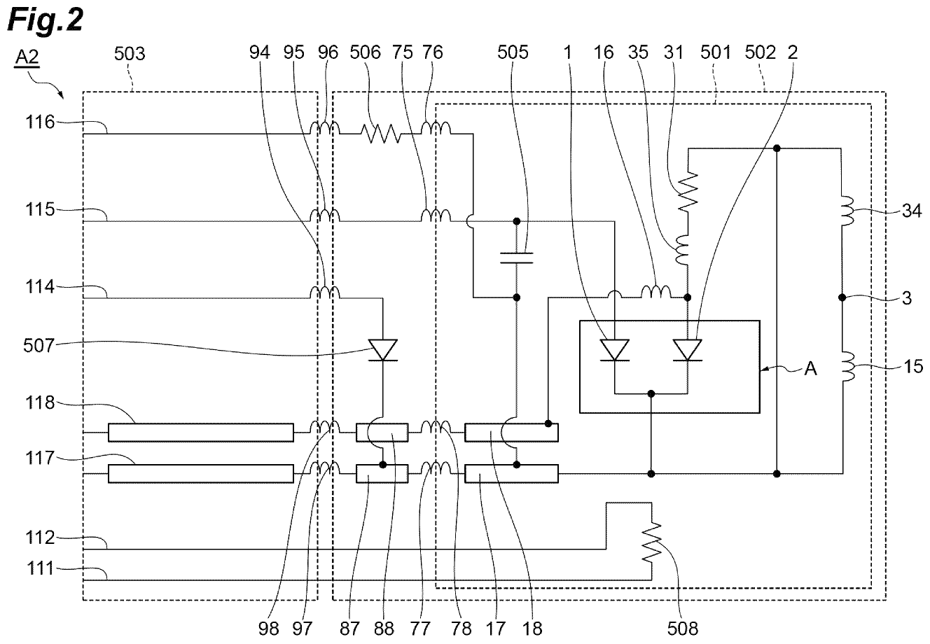

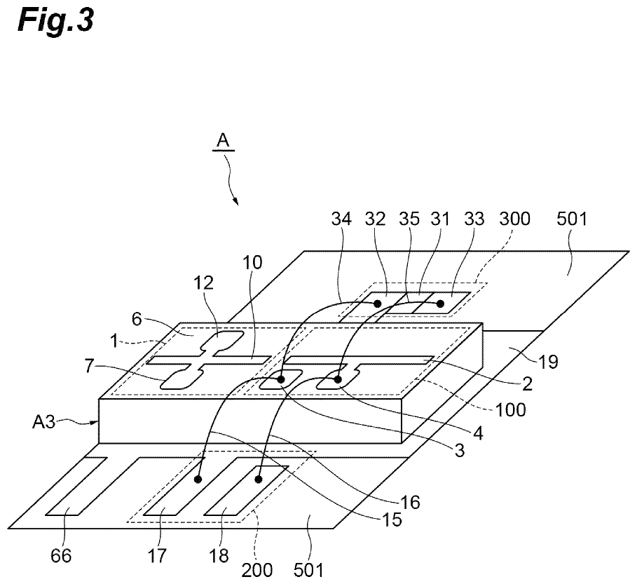

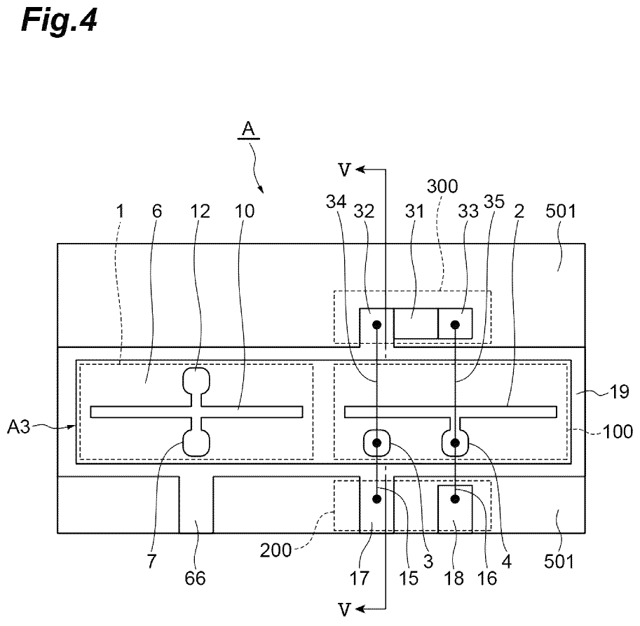

FIG. 1 is a plan view illustrating a transmitting small-sized optical device A1 according to a first embodiment of the present disclosure. FIG. 2 is a circuit diagram illustrating a circuit A2 included in the transmitting small-sized optical device A1. FIG. 3 is a perspective view illustrating a semiconductor light-emitting device A included in the transmitting small-sized optical device A1. FIG. 4 is a plan view illustrating the semiconductor light-emitting device A. The configuration of the transmitting small-sized optical device A1 will be described with reference to FIGS. 1 to 4.

As illustrated in FIG. 1, the transmitting small-sized optical device A1 includes a package 509, a substrate 501 (a chip-on carrier), a substrate 502 (a mount carrier), and a substrate 503. The package 509 accommodates the substrate 501, the substrate 502, and the substrate 503. A wiring pattern 114, a wiring pattern 115, a wiring pattern 116, ground potential lines 117 and 119, signal lines 118 and 121, a wiring pattern 111, a wiring pattern 112, and a driver IC 504 are provided on the substrate 503. The wiring pattern 114, the wiring pattern 115, the wiring pattern 116, the ground potential line 117, the signal line 118, the wiring pattern 111, and the wiring pattern 112 extend from one side wall of the package 509 toward the substrate 502 and are connected to an external circuit outside of the transmitting small-sized optical device A1 via terminals which are not illustrated. The material of the substrate 501 is, for example, an insulator such as a resin. The material of the wiring pattern 114, the wiring pattern 115, the wiring pattern 116, the ground potential lines 117 and 119, the signal lines 118 and 121, the wiring pattern 111, and the wiring pattern 112 is, for example, a metal. The signal line 118 causes a high-frequency modulation signal input from the outside of the transmitting small-sized optical device A1 to propagate. The ground potential line 117 holds a ground potential (a reference potential) input from the outside of the transmitting small-sized optical device A1. The signal line 118 and the ground potential line 117 constitute a transmission line. The ground potential line 119 and the signal line 121 also constitute a transmission line. An input terminal of the driver IC 504 is connected to the ground potential line 117 and the signal line 118. An output terminal of the driver IC 504 is connected to the ground potential line 119 and the signal line 121. The driver IC 504 amplifies the modulation signal from the signal line 118 and outputs the amplified modulation signal to the signal line 121.

As illustrated in FIG. 2, the substrate 502 is disposed along with the substrate 503. A wiring pattern 84, a wiring pattern 85, a wiring pattern 86, a ground potential line 87, a signal line 88, a thermistor 506, a monitoring photodiode 507, and a lens L are provided on the substrate 502. The wiring pattern 86 is connected to the wiring pattern 116 by a wire 96. The wiring pattern 85 is connected to the wiring pattern 115 by a wire 95. The wiring pattern 84 is connected to the wiring pattern 114 by a wire 94. The ground potential line 87 is connected to the ground potential line 119 by a wire 97. The signal line 88 is connected to the signal line 121 by a wire 98. The material of the substrate 502 is, for example, an insulator such as ceramics. The material of the wiring pattern 84, the wiring pattern 85, the wiring pattern 86, the ground potential line 87, and the signal line 88 is, for example, a metal. The thermistor 506 is provided on the wiring pattern 86. The thermistor 506 indicates a resistance value depending on the temperature. The resistance value is detected by an external circuit outside of the transmitting small-sized optical device A1 via the wiring pattern 86, the wire 96, and the wiring pattern 116. The monitoring photodiode 507 is connected between the wiring pattern 84 and the ground potential line 87. In order to make an average intensity of emission light M constant, the monitoring photodiode 507 detects backlight emitted from an optical modulator integrated semiconductor laser A3 (which will be described later) of the semiconductor light-emitting device A. The monitoring photodiode 507 outputs an electrical signal based on the intensity of the backlight to the external circuit outside of the transmitting small-sized optical device A1 via the wiring pattern 84, the wire 94, and the wiring pattern 114. The lens L is optically coupled to a light emission end of the semiconductor light-emitting device A and collimates emission light M emitted from the optical modulator integrated semiconductor laser A3.

A temperature control element (TEC) 508 (which is illustrated in only FIG. 2) is provided on the rear side of the substrate 502. One electrode of the TEC 508 is connected to the wiring pattern 111 by a wire 91. The other electrode of the TEC 508 is connected to the wiring pattern 112 by a wire 92. Electric power for driving the TEC 508 is input from an external circuit outside of the transmitting small-sized optical device A1 via the wiring pattern 111 and the wiring pattern 112. The external circuit outside of the transmitting small-sized optical device A1 controls a magnitude of the electric power for driving the TEC 508 based on a peripheral temperature of the semiconductor light-emitting device A, that is, a resistance value of the thermistor 506. Accordingly, the temperature of the optical modulator integrated semiconductor laser A3 is maintained at a predetermined temperature, and the wavelength of emission light M emitted from the semiconductor light-emitting device A is maintained at a predetermined wavelength.

The substrate 501 is provided on the substrate 502. A ground potential line 66, a wiring pattern 65, a bypass capacitor 505, and a semiconductor light-emitting device A are provided on the substrate 501. The material of the substrate 501 is, for example, an insulator such as ceramics. The material of the ground potential line 66 and the wiring pattern 65 is, for example, a metal. As illustrated in FIG. 3, the semiconductor light-emitting device A includes an optical modulator integrated semiconductor laser A3, a ground pattern 19, a transmission line 200, and a termination unit 300. The transmission line 200 includes a ground potential line 17 and a signal line 18. The ground potential line 17 is provided on the optical modulator integrated semiconductor laser A3 side with respect to the signal line 18. The ground potential line 17 and the signal line 18 have an L-shape in a plan view. The ground pattern 19 has a rectangular shape in a plan view. The material of the ground potential line 17, the signal line 18, and the ground pattern 19 is, for example, a metal. The ground pattern 19 is connected to the ground potential line 17. The ground potential line 17 is connected to the ground potential line 87 by a wire 78. The ground potential line 66 is provided on the opposite side to the ground potential line 17 with respect to the ground pattern 19. A ground terminal of the thermistor 506 is connected to the ground potential line 66 by a wire 76. The bypass capacitor 505 is provided on the ground potential line 66. A lower electrode of the bypass capacitor 505 is connected to the ground potential line 66. An upper electrode of the bypass capacitor 505 is connected to the wiring pattern 65 by a wire 55.

The optical modulator integrated semiconductor laser A3 includes a laser unit 1 and an optical modulation unit 100. The optical modulator integrated semiconductor laser A3 is provided on the ground pattern 19. The laser unit 1 includes an active region and generates a laser beam with an optical intensity which is temporally constant when a current is supplied to the active region. The optical modulation unit 100 modulates the laser beam output from the laser unit 1 and outputs the modulated emission light M. The backlight is a laser beam output from the laser unit 1 without passing through the optical modulation unit 100. The laser unit 1 and the optical modulation unit 100 are monolithically formed in the optical modulator integrated semiconductor laser A3.

The laser unit 1 is provided near the substrate 503 with respect to the optical modulation unit 100. The laser unit 1 includes an active region and outputs a laser beam. The laser unit 1 includes a drive electrode 10, a pad 7, and a pad 12 on the surface thereof. The drive electrode 10 extends in a laser resonating direction (a longitudinal direction of the optical modulation unit 100) and supplies a current to the active region. The pad 7 is arranged side by side with the drive electrode 10 in a direction crossing an extending direction of the drive electrode 10 and is connected to the drive electrode 10. The pad 12 is arranged on the opposite side to the pad 7 with respect to the drive electrode 10 and is connected to the drive electrode 10. The pad 7 is connected to the upper electrode of the bypass capacitor 505 by a wire 9. Accordingly, a drive current is supplied to the drive electrode 10 from the outside of the transmitting small-sized optical device A1 via the wiring pattern 115, the wiring pattern 85, the wiring pattern 65, the upper electrode of the bypass capacitor 505, and the pad 7. The wire 9 may be connected to the pad 12 instead of the pad 7.

The optical modulation unit 100 includes a modulation electrode 2, a pad 3 (a first pad), and a pad 4 (a signal pad). The optical modulation unit 100 includes a modulation region and modulates a laser beam by transmitting or cutting off the laser beam with supply of a current to the modulation region. The modulation electrode 2 supplies a modulation current (a modulation signal) to the modulation region. Accordingly, the modulation electrode 2 transmits or cuts off the laser beam based on the modulation signal input to the modulation region. The modulation electrode 2 extends in the same direction as the progressing direction of the laser beam in a plan view. On the top surface of the optical modulator integrated semiconductor laser A3, the modulation electrode 2 is provided at the center in a direction perpendicular to the progressing direction of the laser beam.

One end of the ground potential line 17 is connected to the ground potential line 87 by a wire 77. One end of the signal line 18 is connected to the signal line 88 by a wire 78. The other end of the ground potential line 17 is connected to the pad 3 by a wire 15 (a second wire). The other end of the signal line 18 is connected to the pad 4 by a wire 16 (a first wire). The wire 15 and the wire 16 are bonding wires formed of, for example, Au. A sectional diameter of the wire 15 and the wire 16 is, for example, 25 μm. The pad 4 is connected to the modulation electrode 2. The pad 3 is provided on the laser unit 1 side (one side) with respect to the pad 4. The pad 3 and the pad 4 are provided on the transmission line 200 side with respect to the modulation electrode 2. The pad 3 is provided side by side with the pad 4 along the longitudinal direction of the modulation electrode 2. The pad 4 is provided at the center in the progressing direction of the laser beam in the optical modulation unit 100. The pad 3 and the pad 4 have a film shape and have a substantially rectangular shape in a plan view. The material of the pad 3 and the pad 4 is metal and is, for example, gold (Au). The wire 15 is provided along with the wire 16. As illustrated in FIG. 4, for example, the wire 15 and the wire 16 are provided in parallel with each other in a plan view. An interval between the wire 15 and the wire 16 is, for example, several tens of μm.

The termination unit 300 includes a first wiring pattern 33, a termination resistor 31, and a second wiring pattern 32. The termination unit 300 is provided on the opposite side to the transmission line 200 with respect to the optical modulation unit 100 and reduces reflection of a modulation signal. One end of the termination resistor 31 is connected to the first wiring pattern 33. The other end of the termination resistor 31 is connected to the second wiring pattern 32. The first wiring pattern 33 is connected with the pad 4 by a wire 35 (a fourth wire). The second wiring pattern 32 is connected with the pad 3 by a wire 34 (a fifth wire). The wire 34 and the wire 35 are provided in parallel with each other. The wire 34 and the wire 35 are, for example, bonding wires. A sectional diameter of the wire 34 and the wire 35 is, for example, 25 μm. The second wiring pattern 32 is connected to the ground pattern 19 and thus holds the ground potential. The first wiring pattern 33 and the second wiring pattern 32 have a film shape and have a substantially rectangular shape in a plan view. The material of the first wiring pattern 33 and the second wiring pattern 32 is, for example, gold (Au). The termination resistor 31 has a rectangular shape in a plan view. The resistance value of the termination resistor 31 is, for example, 50Ω.

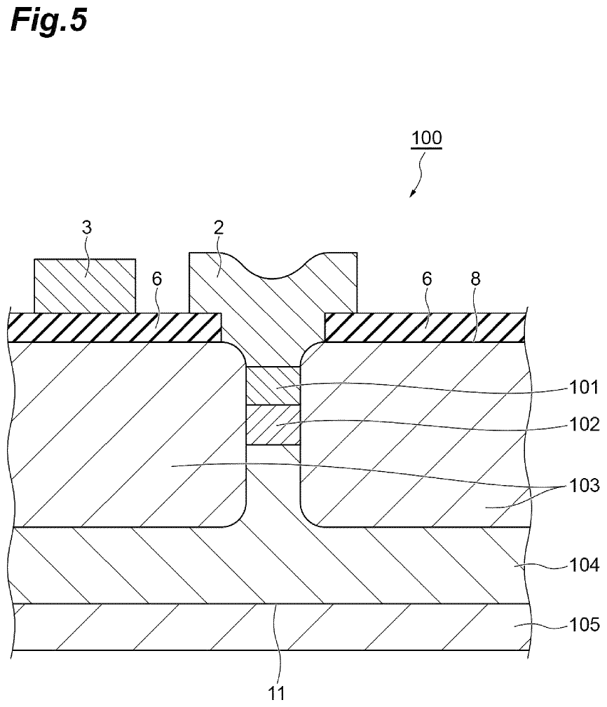

FIG. 5 is a sectional view along line V-V in FIG. 4 and illustrates a cross-section of the optical modulation unit 100, which is perpendicular to the progressing direction of a laser beam. The optical modulator integrated semiconductor laser A3 includes a top surface 8 and a bottom surface 11. The optical modulation unit 100 includes an insulating film 6 on the top surface 8. The pad 4 and the pad 3 are provided on the insulating film 6. The pad 3 is electrically isolated from the pad 4. A resistance value between the pad 3 and the pad 4 is, for example, several hundreds of Ω or larger. The material of the insulating film 6 is, for example, SiN or SiO₂. The optical modulation unit 100 includes a p-InP layer 101, a light absorbing layer 102, a pair of semi-insulating InP regions 103, and an n-InP layer 104 in addition to the modulation electrode 2, the pad 3, and the insulating film 6. The light absorbing layer 102 and the p-InP layer 101 are provided on the n-InP layer 104, and the light absorbing layer 102 is interposed between the n-InP layer 104 and the p-InP layer 101. A part of the n-InP layer 104, the light absorbing layer 102, and the p-InP layer 101 are formed in a mesa shape on the remaining part of the n-InP layer 104, and the pair of semi-insulating InP regions 103 are in contact with both side surfaces of the mesa to form a mesa buried structure. The lower electrode 105 is provided on the bottom surface 11. The lower electrode 105 is in contact with the n-InP layer 104. The top surface of the semi-insulating InP regions 103 constitute the top surface 8. The insulating film 6 includes an opening at the center thereof, and the modulation electrode 2 is provided in the opening. The modulation electrode 2 is provided on the p-InP layer 101 and is in contact with the p-InP layer 101. The n-InP layer 104 serves as a lower clad layer. The p-InP layer 101 serves as an upper clad layer and a contact layer.

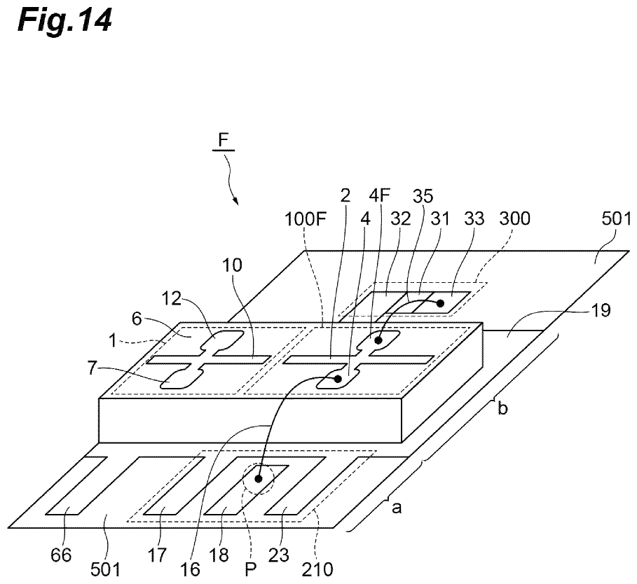

Advantages of the semiconductor light-emitting device A having the aforementioned configuration will be described below through comparison with a comparative example illustrated in FIG. 14. The wire 15 is connected between the pad 3 and the ground potential line 17. Accordingly, the wire 15 holding the ground potential can be disposed side by side with the wire 16. Since the wire 16 and the wire 15 are arranged side by side, a modulation signal progresses side by side with the ground potential even after the modulation signal has gotten away from the signal line 18.

FIG. 14 is a perspective view illustrating a semiconductor light-emitting device F according to a comparative example. The semiconductor light-emitting device F illustrated in FIG. 14 includes an optical modulation unit 100F instead of the optical modulation unit 100 according to this embodiment. The semiconductor light-emitting device F does not include the wire 15 and the wire 34 according to this embodiment. The optical modulation unit 100F is different from the optical modulation unit 100 in that the pad 3 is not provided and a pad 4F is provided and is the same as the optical modulation unit 100 in the other points. The pad 4F is provided on the opposite side to the pad 4 with respect to the modulation electrode 2 and is connected to the modulation electrode 2. In this comparative example, the wire 35 is connected to the pad 4F. In this comparative example, high-frequency characteristics are improved by performing design such that a characteristic impedance value of a transmission line 210 from an external drive circuit to the semiconductor light-emitting device F is close to a value of the termination resistor 31. However, the ground potential line 17 and the ground potential line 23 of the transmission line 210 are provided in only a region ‘a’ including the transmission line 210 and are not provided in a region ‘b’ including the optical modulation unit 100F. Accordingly, a modulation signal input to the semiconductor light-emitting device F and getting away from the signal line 18 and progressing in the wire 16 progresses away from the ground potential line 17 and the ground potential line 23 after passing through a junction between the transmission line 210 (the region ‘a’) and the optical modulation unit 100F (the region ‘b’). Accordingly, an input impedance is less likely to be matched, and mismatch in impedance between the signal line 18 and the wire 16 is likely to increase. When mismatch in impedance increases, the modulation signal is reflected by a boundary (a change point P) between the signal line 18 and the wire 16 and thus a loss of the modulation signal increases. Accordingly, there is concern the modulation signal may not be satisfactorily transmitted to the modulation electrode 2.

In the semiconductor light-emitting device A according to the first embodiment of the present disclosure, the wire 16 holding the ground potential is arranged side by side with the wire 15 as described above. Accordingly, the modulation signal progresses side by side with the ground potential even after the modulation signal has gotten away from the signal line 18. As a result, the characteristic impedance of the wire 16 becomes close to a predetermined value (for example, 50Ω), and mismatch in impedance between the signal line 18 and the wire 16 decreases. Accordingly, it is possible to reduce a loss of the modulation signal (for example, a modulation signal of a high-frequency region equal to or higher than several tens of GHz) due to mismatch in impedance. The wire 34 is connected to the pad 3 and thus holds the ground potential. In addition, the wire 34 and the wire 35 are arranged side by side with each other. Accordingly, the modulation signal propagating in the wire 35 progresses side by side with the ground potential. As a result, the characteristic impedance of the wire 35 becomes close to a predetermined value (for example, 50Ω), and mismatch in impedance between the wire 16 and the wire 35 decreases. Accordingly, it is possible to further reduce a loss of the modulation signal due to mismatch in impedance.

As in this embodiment, the optical modulation unit 100 may include the insulating film 6 on the top surface 8, and the pad 3 and the pad 4 may be provided on the insulating film 6. When the pad 3 and the pad 4 are provided on the insulating film 6, the pad 3 and the pad 4 can be electrically isolated from each other. Accordingly, it is possible to prevent a modulation signal input to the pad 4 from leaking into the pad 3. As a result, it is possible to efficiently allow the modulation signal input to the pad 4 to reach the modulation electrode 2.

As in this embodiment, the pad 3 may be electrically isolated from the pad 4. The pad 3 holds the ground potential. Accordingly, by electrically isolating the pad 3 and the pad 4, it is possible to prevent the modulation signal input to the pad 4 from leaking into the pad 3. As a result, it is possible to efficiently allow the modulation signal input to the pad 4 to reach the modulation electrode 2.

As in this embodiment, the pad 3 may be provided in the optical modulation unit 100. Accordingly, the pad 3 is disposed at a position closer to the pad 4. As a result, a distance between the wire 16 through which the modulation signal passes and the wire 15 holding the ground potential becomes smaller, and match in input impedance is further facilitated.

As in this embodiment, the wire 15 and the wire 16 may be provided in parallel with each other. Accordingly, it is possible to more easily reduce mismatch in impedance between the signal line 18 and the wire 16. As a result, it is possible to further reduce a loss of the modulation signal due to mismatch in impedance.

### (First Modification)

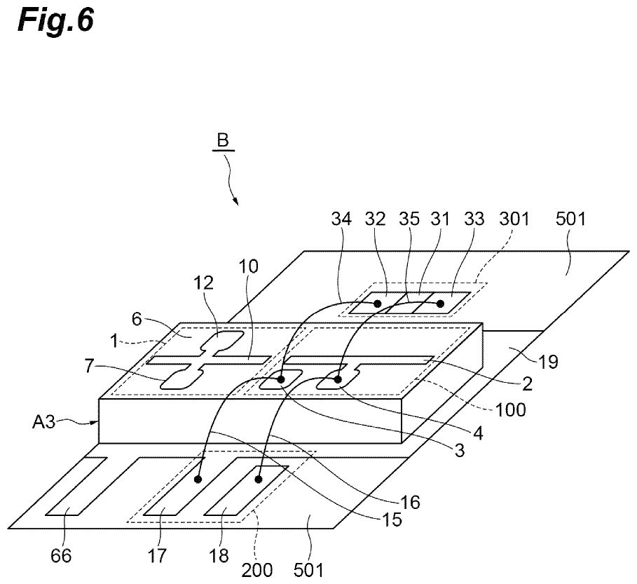

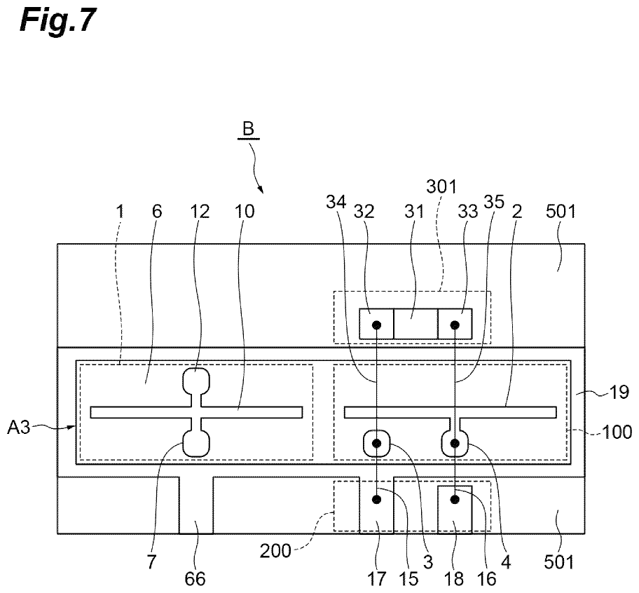

FIG. 6 is a perspective view illustrating a semiconductor light-emitting device B according to a first modification. FIG. 7 is a plan view illustrating the semiconductor light-emitting device B. The semiconductor light-emitting device B is different from the semiconductor light-emitting device A in the following points and is the same in the other points. The semiconductor light-emitting device B includes a termination unit 301 instead of the termination unit 300 of the semiconductor light-emitting device A. The termination unit 301 includes a first wiring pattern 33, a termination resistor 31, and a second wiring pattern 32. Unlike the first embodiment, in this modification, the second wiring pattern 32 is not connected to a ground pattern 19. A resistance value between the second wiring pattern 32 and the ground pattern 19 is, for example, several hundreds of (or more.

In this modification, since the second wiring pattern 32 and the ground pattern 19 are not connected to each other, the whole amount of current of a modulation current returning to the ground via the termination resistor 31 passes through the wire 34, and thus the amount of current of the input modulation current is balanced with the amount of current flowing in a wire holding the ground potential. As a result, it is possible to improve accuracy of match in input impedance.

### (Second Modification)

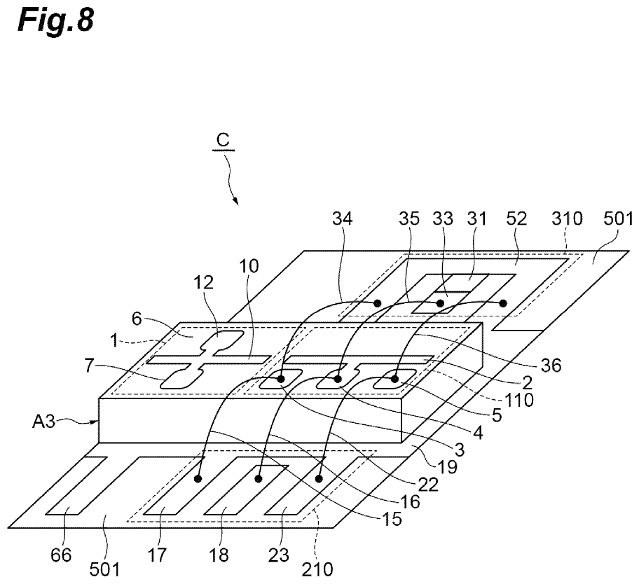

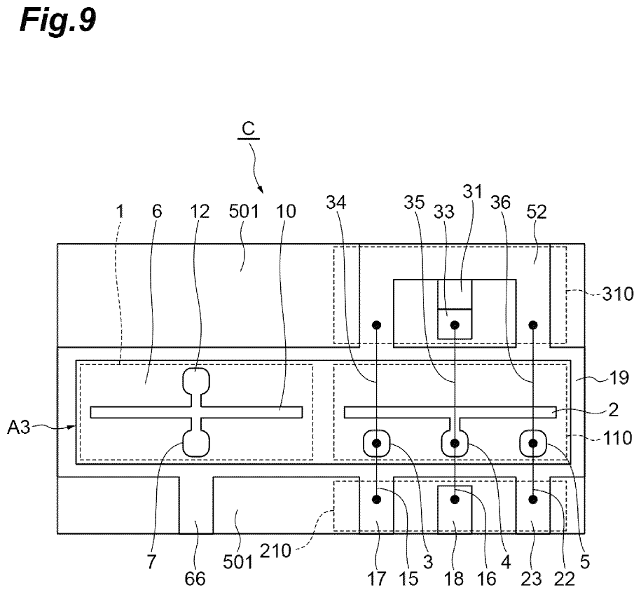

FIG. 8 is a perspective view illustrating a semiconductor light-emitting device C according to a second modification. FIG. 9 is a plan view illustrating the semiconductor light-emitting device C. The semiconductor light-emitting device C is different from the semiconductor light-emitting device A in the following points and is the same in the other points. The semiconductor light-emitting device C includes a transmission line 210 instead of the transmission line 200 in the embodiment and further includes a wire 22 (a third wire). The wire 22 is provided in parallel with the wire 15 and the wire 16. The wire 22 is, for example, a bonding wire. A diameter of a cross-section of the wire 22 is 25 μm, for example. The optical modulator integrated semiconductor laser A3 of the semiconductor light-emitting device C includes an optical modulation unit 110 instead of the optical modulation unit 100 in the embodiment. The optical modulation unit 110 further includes a pad 5 (a second pad) in addition to the configuration of the optical modulation unit 100. The pad 5 is provided on the opposite side to (the other side of) the pad 3 with respect to the pad 4 and is provided side by side with the pad 3 and the pad 4 along the longitudinal direction of the modulation electrode 2. The pad 5 is provided near the transmission line 210 with respect to the modulation electrode 2. The transmission line 210 further includes a ground potential line 23 in addition to the ground potential line 17 and the signal line 18 according to the embodiment. The signal line 18 is provided between the ground potential line 17 and the ground potential line 23. Accordingly, the transmission line 210 constitutes a coplanar line. The pad 5 is connected to the ground potential line 23 by a wire 22. The pad 5 has a film shape and has a substantially rectangular shape in a plan view. The material of the pad 5 is, for example, gold (Au). The wire 22 is provided on the opposite side to the wire 15 with respect to the wire 16. The wire 22 is provided side by side with the wire 16. For example, the wire 16 and the wire 22 are provided in parallel with each other in a plan view.

The semiconductor light-emitting device C further includes a termination unit 310 and a wire 36 (a sixth wire). The wire 34, the wire 35, and the wire 36 are provided in parallel with each other. The wire 34, the wire 35, and the wire 36 are, for example, bonding wires. A sectional diameter of the wire 34, the wire 35, and the wire 36 is, for example, 25 μm. The termination unit 310 is provided on the opposite side to the transmission line 210 with respect to the optical modulation unit 110 and reduces reflection of the modulation signal. The termination unit 310 includes the first wiring pattern 33, the termination resistor 31, and the second wiring pattern 52. The second wiring pattern 52 has a U-shape in a plan view. One end of the termination resistor 31 is connected to the first wiring pattern 33. The other end of the termination resistor 31 is connected to the center of the second wiring pattern 52. The first wiring pattern 33 is connected with the pad 4 by the wire 35. One end of the second wiring pattern 52 is connected with the pad 3 by the wire 34. The other end of the second wiring pattern 52 is connected with the pad 5 by the wire 36. The second wiring pattern 52 holds the ground potential because one end and the other end thereof are connected to the ground pattern 19. The material of the first wiring pattern 33 and the second wiring pattern 52 is, for example, gold (Au). The termination resistor 31 has a rectangular shape in a plan view. The resistance value of the termination resistor 31 is, for example, 50Ω.

In this modification, the wire 22 is connected between the ground potential line 23 and the pad 5. The wire 22 holds the ground potential. Accordingly, the wire 16 arranged side by side with the wire 15 and the wire 22 is sandwiched in the ground potential. In this case, a modulation signal passing through the wire 16 advances while being sandwiched by the ground potential. Accordingly, the characteristic impedance of the wire 16 becomes close to a predetermined value (for example, 50Ω), and mismatch in impedance between the signal line 18 and the wire 16 further decreases. Accordingly, it is possible to further reduce a loss of a modulation signal (for example, a modulation signal of a high-frequency region equal to or higher than several tens of GHz) due to mismatch in impedance. The wire 34 and the wire 36 are connected to the pad 3 and the pad 5, respectively, and thus hold the ground potential. Accordingly, the wire 35 arranged side by side with the wire 34 and the wire 36 is sandwiched in the ground potential. Therefore, the modulation signal passing through the wire 35 advances while being sandwiched by the ground potential. Accordingly, the characteristic impedance of the wire 35 becomes closer to a predetermined value (for example, 50Ω), and mismatch in impedance between the wire 16 and the wire 35 further decreases. As a result, it is possible to further reduce a loss of the modulation signal due to mismatch in impedance.

### (Third Modification)

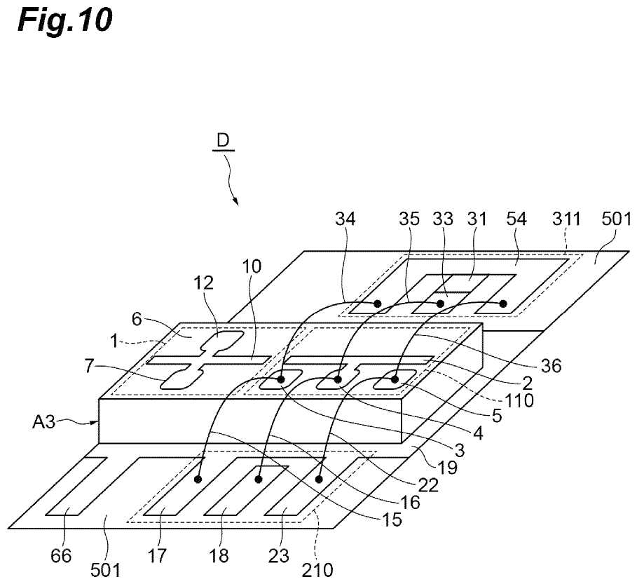

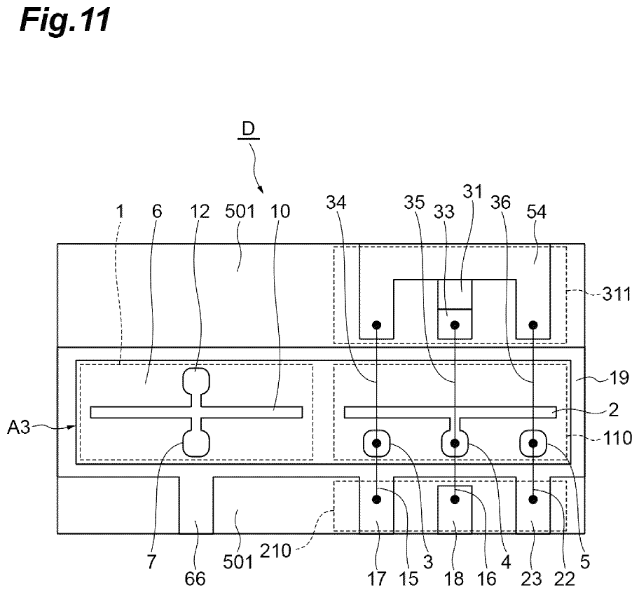

FIG. 10 is a perspective view illustrating a semiconductor light-emitting device D according to a third modification. FIG. 11 is a plan view illustrating the semiconductor light-emitting device D. The semiconductor light-emitting device D is different from the semiconductor light-emitting device C in the following points and is the same in the other points. The semiconductor light-emitting device D includes a termination unit 311 instead of the termination unit 310 of the semiconductor light-emitting device C. The termination unit 311 includes a first wiring pattern 33, a termination resistor 31, and a second wiring pattern 54. Unlike the second modification, in this modification, the second wiring pattern 54 and the ground pattern 19 are not connected to each other. A resistance value between the second wiring pattern 54 and the ground pattern 19 is, for example, several hundreds of Ω or more.

In this modification, since the second wiring pattern 54 and the ground pattern 19 are not connected to each other, the whole amount of current of a modulation current returning to the ground via the termination resistor 31 passes through the wire 34 or the wire 36, and thus the amount of current of the input modulation current is balanced with the amount of current flowing in a wire holding the ground potential. As a result, it is possible to improve accuracy of match in input impedance.

### (Fourth Modification)

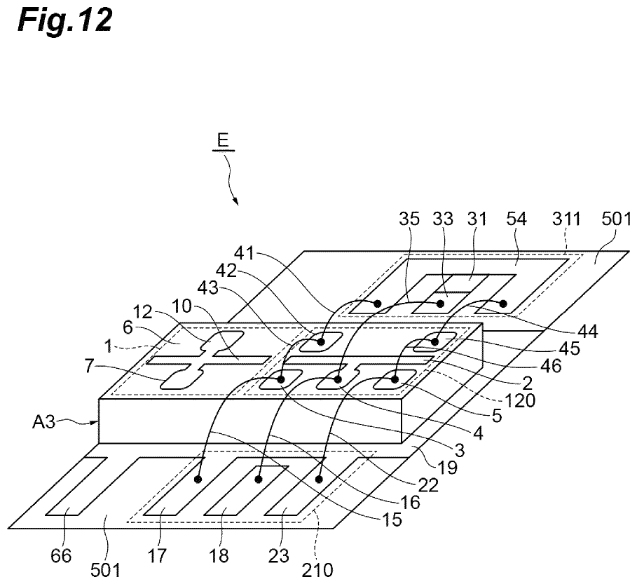

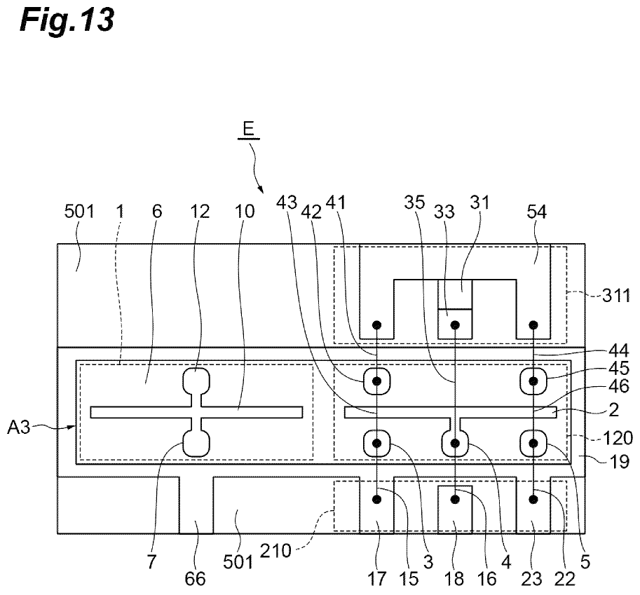

FIG. 12 is a perspective view illustrating a semiconductor light-emitting device E according to a fourth modification. FIG. 13 is a plan view illustrating the semiconductor light-emitting device E according to the fourth modification. The semiconductor light-emitting device E is different from the semiconductor light-emitting device D in the following points and is the same in the other points. The optical modulator integrated semiconductor laser A3 of the semiconductor light-emitting device E includes an optical modulation unit 120 instead of the optical modulation unit 110. The semiconductor light-emitting device E further includes a wire 41, a wire 43, a wire 44, and a wire 46 instead of the wire 34 and the wire 36. The wire 41, the wire 43, the wire 44, and the wire 46 are, for example, bonding wires. A sectional diameter of the wire 41, the wire 43, the wire 44, and the wire 46 is, for example, 25 μm. The optical modulation unit 120 further includes a pad 42 and a pad 45. The pad 42 and the pad 45 are provided near the termination unit 311 with respect to the modulation electrode 2 (that is, the opposite side to the pad 3 and the pad 5 with respect to the modulation electrode 2). The pad 42 and the pad 45 are provided side by side along the longitudinal direction of the modulation electrode 2. The pad 42 is provided near the laser unit 1 with respect to the pad 45. The material of the pad 42 and the pad 45 is, for example, gold (Au). The pad 42 is connected to one end of the second wiring pattern 54 by the wire 41 and is connected to the pad 3 by the wire 43. The pad 45 is connected to the other end of the second wiring pattern 54 by the wire 44 and is connected to the pad 5 by the wire 46. The pad 42 and the pad 45 have a film shape and have a substantially rectangular shape in a plan view. The wire 43 and the wire 41 are provided in parallel with the wire 35 in a plan view. The wire 35 is provided in parallel with the wire 46 and the wire 44 in a plan view.

A distance between the wire 35 and both the wire 43 and the wire 41 can be stably maintained by the pad 42. A distance between the wire 35 and both the wire 44 and the wire 46 can be stably maintained by the pad 45. The wire 43, the wire 41, the wire 44, and the wire 46 hold the ground potential. Accordingly, the wire 35 arranged side by side with these wires is sandwiched in the ground potential. Therefore, the modulation signal passing through the wire 35 advances while being sandwiched by the ground potential. Accordingly, the characteristic impedance of the wire 35 becomes closer to a predetermined value (for example, 50Ω), and mismatch in impedance between the wire 16 and the wire 35 further decreases. As a result, it is possible to further reduce a loss of the modulation due to mismatch in impedance.

The optical modulator integrated semiconductor laser and the semiconductor light-emitting device according to the present disclosure are not limited to the aforementioned embodiment and the aforementioned modifications and can be modified in various forms. For example, in the embodiment, the pad 3 is provided in the optical modulation unit 100, but the arrangement of the pad 3 is not particularly limited in the optical modulator integrated semiconductor laser A3. For example, the pad 3 may be provided in the laser unit 1.

In the embodiment, the pad 3 is provided on the insulating film 6, and thus the pad 3 is not directly connected to the ground potential of the optical modulator integrated semiconductor laser A3. The present disclosure is not limited to this embodiment, and for example, the pad 3 may be provided on the n-InP layer 104 and may be in contact with the n-InP layer 104. Since the pad 3 is connected to the ground potential via the wire 15, the aforementioned advantages can be achieved with a configuration in which the pad 3 is connected to a part holding the ground potential such as the n-InP layer 104.

In the embodiment, the wire 15 and the wire 16 are parallel to each other, but the wire 15 and the wire 16 may not be parallel to each other. Similarly, in the first modification, the wire 22 and the wire 16 may not be parallel to each other. In this case, the aforementioned advantages can be achieved by arranging the wire 15 and the wire 16 side by side with each other (or with the wire 16 interposed between the wire 15 and the wire 22).

In the embodiment, an example in which the ground potential line 17 of the transmission line 200 is provided on the substrate 502 side by side with the signal line 18 has been described above, but the configuration of the transmission line is not limited thereto. For example, even when the transmission line is configured as a so-called micro strip line in which the ground potential line is provided on the bottom surface of the substrate 501, the aforementioned advantages can be achieved.

What is claimed is:

1. An optical modulator integrated semiconductor laser comprising:
a laser unit outputs a laser beam;
an optical modulation unit modulates the laser beam;
a signal pad for connection to a first wire for inputting a modulation signal to the optical modulation unit; and
a first pad for connection to a second wire holding a ground potential.

2. The optical modulator integrated semiconductor laser according to claim 1, further comprising a second pad for connection to a third wire holding the ground potential.

3. The optical modulator integrated semiconductor laser according to claim 1, wherein the first pad and the signal pad are provided in the optical modulation unit.

4. A semiconductor light-emitting device comprising:
the optical modulator integrated semiconductor laser according to claim 1; and
a transmission line connected to the optical modulation unit to transmit a modulation signal,
wherein the transmission line includes a signal line for transmitting the modulation signal and a ground potential line holding the ground potential,
wherein the signal pad is connected with the signal line by the first wire, and
wherein the first pad provided on one side of the signal pad is connected with the ground potential line by the second wire.

5. The semiconductor light-emitting device according to claim 4, wherein a second pad is provided on another side of the signal pad.

6. The semiconductor light-emitting device according to claim 4, further comprising:
a termination unit provided on an opposite side of the transmission line with respect to the optical modulation unit and configured to reduce reflection of the modulation signal;
a fourth wire; and
a fifth wire,
wherein the termination unit includes a first wiring pattern, a resistor of which one end is connected to the first wiring pattern, and a second wiring pattern to which another end of the resistor is connected,
wherein the first wiring pattern is connected with the signal pad by the fourth wire, and
wherein the second wiring pattern is connected with the first pad by the fifth wire.

7. The semiconductor light-emitting device according to claim 6, further comprising:
a sixth wire; and
a second pad provided on another side of the signal pad,
wherein the second wiring pattern is connected with the second pad by the sixth wire.

8. The semiconductor light-emitting device according to claim 7, wherein the second wiring pattern is connected to only the resistor, the fifth wire, and the sixth wire.

9. The semiconductor light-emitting device according to claim 6, wherein the second wiring pattern is connected to only the resistor and the fifth wire.

10. The semiconductor light-emitting device according to claim 4, wherein the first wire and the second wire are provided in parallel with each other.
